(19) United States
(12) Patent Application Publication
(10) Pub. No.: US 2026/0126335 A1
(43) Pub. Date: May 7, 2026

(54) METHOD AND SYSTEM FOR MONITORING AND PREDICTING LEAK IN LIQUID COOLING SYSTEM OF ELECTRONIC DEVICE

(71) Applicant: Wistron Corporation, New Taipei City (TW)

(72) Inventors: Tung Yang TANG, New Taipei City (TW); Liping PAN, New Taipei City (TW); Meng Chao KAO, New Taipei City (TW); Chu Chia TSAI, New Taipei City (TW); Wen Hua LIU, New Taipei City (TW)

(21) Appl. No.: 19/009,176

(22) Filed: Jan. 3, 2025

(30) Foreign Application Priority Data
Nov. 1, 2024 (TW) 113142004

(51) Int. Cl. G01M 3/24; F17D 5/06; G01N 29/44; G01N 29/46; H05K 7/20

(52) U.S. Cl. CPC G01M 3/243; F17D 5/06; G01N 29/4418; G01N 29/4481; G01N 29/46; H05K 7/20327

(57) ABSTRACT

A leak monitoring technology is provided. In some embodiments, a real-time audio signal of fluid flow in a pipeline is received in real time. The real-time audio signal is converted into a time-frequency spectrum. Image recognition is performed on the time-frequency spectrum, to determine whether there is a leak in the pipeline.

### CROSS-REFERENCE TO RELATED APPLICATION

This non-provisional application claims priority under 35 U.S.C. § 119(a) to Patent Application No. 113142004 filed in Taiwan, R.O.C. on Nov. 1, 2024, the entire contents of which are hereby incorporated by reference.

### BACKGROUND

### Technical Field

The disclosure relates to a method and system for monitoring and predicting a leak in a liquid cooling system of an electronic device.

### Related Art

With the advent of the high-computing power era driven by Artificial Intelligence (AI), the demand for high-performance computing and high-frequency, high-speed data transmission has been steadily increasing. This trend has led to a continuous rise in power consumption by servers, driving the advancement of cooling technologies. Currently, air cooling is gradually becoming insufficient to meet thermal management requirements, bringing liquid cooling technology to the forefront. However, liquid cooling still presents a potential risk of leakage, which can result in failures of electronic components.

In conventional technologies, leakage monitoring in liquid cooling systems is predominantly carried out using leak detection cables. These cables are typically deployed beneath the raised floors of data centers or within servers. However, due to their large size and high cost, leak detection cables can only be installed in critical areas. Moreover, they are incapable of detecting minor leaks and generally only trigger detection when leakage has reached a significant level, by which time damage to electronic components or circuits has often already occurred.

### SUMMARY

In view of the above, the disclosure provides a method for monitoring and predicting a leak in a liquid cooling system of an electronic device. The method includes: receiving a real-time audio signal of fluid flow within a pipeline; converting the real-time audio signal into a time-frequency spectrum; and performing image recognition on the time-frequency spectrum, to determine whether there is a leak in the pipeline.

In some embodiments, the step of converting the real-time audio signal into the time-frequency spectrum includes: performing fast Fourier transform on the real-time audio signal, to generate the time-frequency spectrum, where the time-frequency spectrum is a three-dimensional spectrum, and the three-dimensional spectrum includes time information, frequency information, and sound intensity information.

In some embodiments, the step of determining whether there is the leak in the pipeline based on the time-frequency spectrum includes: inputting the time-frequency spectrum into a classification model, to generate a leak determining result of the pipeline. In some embodiments, the classification model is a neural network (NN) model.

In some embodiments, the classification model includes a bidirectional long short-term memory (BLSTM) model, which includes an input layer, a forward long short-term memory layer, a backward long short-term memory layer, a fully connected layer, and an output layer. The input layer is configured to receive the time-frequency spectrum, the forward long short-term memory layer is configured to process forward sequence data in the time-frequency spectrum, the backward long short-term memory layer is configured to process backward sequence data in the time-frequency spectrum, the fully connected layer is configured to integrate outputs of the forward long short-term memory layer and the backward long short-term memory layer, and the output layer is configured to output the corresponding leak determining result.

In some embodiments, after obtaining the leak determining result, the method further includes: determining whether the leak determining result matches a result of an actual current condition; and inputting the time-frequency spectrum into a training dataset, to retrain the classification model through the training dataset if the leak determining result does not match the result of the actual current condition.

In some embodiments, the training dataset includes the following steps: initializing a weight and a bias of the classification model; inputting training data into the classification model, and obtaining a prediction result through forward propagation; calculating a loss function, and evaluating a difference between the prediction result and an actual result; calculating gradients of the weight and the bias by using a backpropagation algorithm, and updating the weight and the bias by using an optimization algorithm, to minimize the loss function; and repeating the above steps until the model converges or reaches a set number of training iterations.

In some embodiments, after the training of the classification model is completed, the method includes the following steps: using test data to perform predictions with the classification model, and evaluating performance of the model; and adjusting a model architecture and a hyperparameter, or retraining the model based on an evaluation result.

In some embodiments, the classification model includes a support vector machine classification model.

In some embodiments, establishing the classification model includes the following steps: providing a plurality of time-frequency spectra corresponding to leakage and non-leakage conditions, and performing image pyramid processing and feature extraction processing on the time-frequency spectra in sequence, and then outputting the processed data to the support vector machine classification model for classification.

In some embodiments, the inputting the time-frequency spectrum into a classification model, to generate a leak determining result of the pipeline includes the following steps: performing image pyramid processing at different scales on time-frequency spectra, to generate a plurality of audio region images with varying scales, and segmenting the audio region images of different scales, to generate a plurality of sub-blocks; calculating at least one feature value of each of the sub-blocks, and determining a texture correlation between each sub-block and a reference model associated with non-leakage conditions; and generating the leak determining result of the pipeline based on the feature value and the texture correlation of each sub-block by using the support vector machine classification model.

In some embodiments, establishing the reference model includes the following steps: averaging pixel values of sub-time-frequency spectra obtained from performing the image pyramid processing on the plurality of time-frequency spectra corresponding to non-leakage conditions, to generate the reference model.

In some embodiments, the at least one feature value of each sub-block includes at least one of a standard deviation and histogram kurtosis of a plurality of pixel values of the sub-block.

In some embodiments, the texture correlation between each sub-block and the reference model is a correlation coefficient of a local binary pattern (LBP) between the sub-block and the reference model.

In view of the above, the disclosure provides a system for monitoring and predicting a leak in a liquid cooling system of an electronic device. The system includes: a receiving module, configured to receive a real-time audio signal of fluid flow within a pipeline; and a processor, coupled to the receiving module, and configured to convert the real-time audio signal into a time-frequency spectrum and perform image recognition on the time-frequency spectrum, to determine whether there is a leak in the pipeline.

In some embodiments, the receiving module includes an automotive audio bus (A2B) and a plurality of miniature microphone units, and the miniature microphone units are arranged in a daisy chain configuration, and are electrically connected to the automotive audio bus.

In some embodiments, the receiving module is arranged on a side of a fluid cooling pipeline of an electronic device, and is adapted to continuously receive the real-time audio signal generated by cooling fluid flow in the pipeline.

In some embodiments, the classification model includes a bidirectional long short-term memory model, which includes an input layer, a forward long short-term memory layer, a backward long short-term memory layer, a fully connected layer, and an output layer. The input layer is configured to receive the time-frequency spectrum, the forward long short-term memory layer is configured to process forward sequence data in the time-frequency spectrum, the backward long short-term memory layer is configured to process backward sequence data in the time-frequency spectrum, the fully connected layer is configured to integrate outputs of the forward long short-term memory layer and the backward long short-term memory layer, and the output layer is configured to output a corresponding leak determining result.

In some embodiments, the classification model includes a support vector machine classification model. The processor is configured to perform image pyramid processing at different scales on time-frequency spectra, to generate a plurality of audio region images with varying scales, and segment the audio region images of different scales, to generate a plurality of sub-blocks; calculate at least one feature value of each of the sub-blocks, and calculate a texture correlation between each sub-block and a reference model associated with non-leakage conditions; and generate the leak determining result of the pipeline based on the feature value and the texture correlation of each sub-block by using the support vector machine classification model.

In view of the above, the disclosure provides a system for monitoring and predicting a leak within a liquid cooling system of an electronic device. The system includes: a receiving module, configured to receive a real-time audio signal of fluid flow in a pipeline; and a processor, coupled to the receiving module, and configured to perform fast Fourier transform on the real-time audio signal, to generate a time-frequency spectrum, and input the time-frequency spectrum into a classification model, to perform image recognition, so as to determine whether there is a leak in the pipeline.

### BRIEF DESCRIPTION OF THE DRAWINGS

FIG. 1 is a system block diagram of a leakage monitoring and prediction system according to some embodiments of the disclosure;

FIG. 2 is a schematic diagram of a leakage monitoring and prediction system according to some embodiments of the disclosure;

FIG. 3A is a schematic diagram of a time-frequency spectrum without leakage;

FIG. 3B is a schematic diagram of a time-frequency spectrum during continuous leakage;

FIG. 4 is a flowchart illustrating the main steps of a leakage monitoring and prediction method according to some embodiments of the disclosure;

FIG. 5 is a schematic diagram illustrating the establishment of a classification model in a leakage monitoring and prediction method according to some embodiments of the disclosure;

FIG. 6 is a flowchart illustrating the leakage determination process in a leakage monitoring and prediction method according to some embodiments of the disclosure;

FIG. 7 is a flowchart illustrating the training of a classification model in a leakage monitoring and prediction method according to some embodiments of the disclosure; and

FIG. 8 is an architecture diagram of a bidirectional long short-term memory (BLSTM) model used in a leakage monitoring and prediction method according to some embodiments of the disclosure.

### DETAILED DESCRIPTION

Various embodiments are described in detail below. However, the embodiments are merely used as examples for description, and do not limit or reduce the protection scope of the disclosure. In addition, some elements are omitted in drawings in the embodiments, to clearly show technical features of the disclosure. Furthermore, same reference numerals indicate same or similar elements in all of the drawings. The drawings of the disclosure are merely examples, which are not necessarily drawn to scale, and not all details are necessarily presented in the drawings.

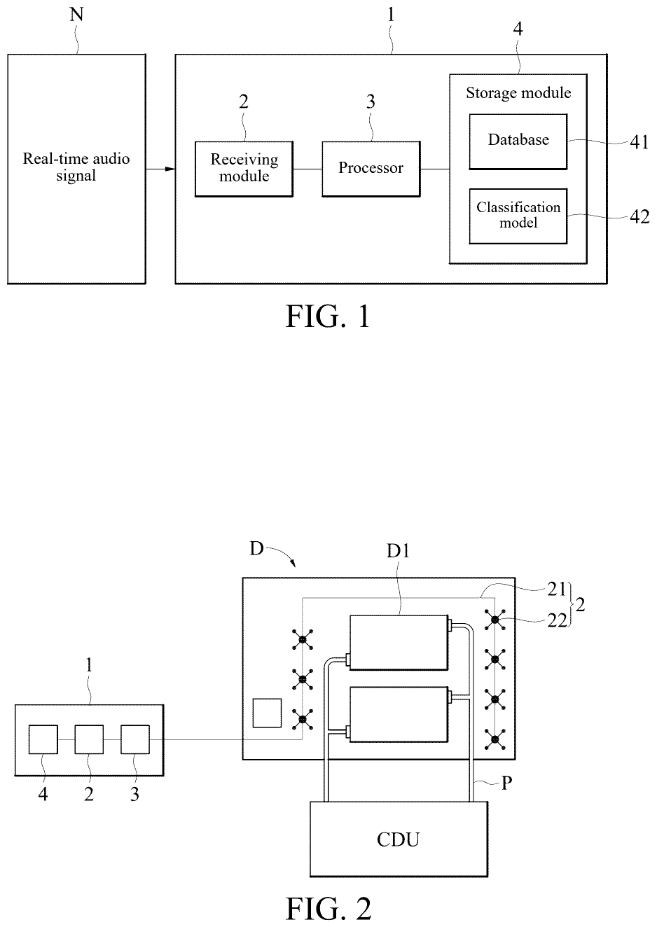

Referring to FIG. 1 and FIG. 2 together, FIG. 1 is a system block diagram of a leakage monitoring and prediction system 1 according to some embodiments of the disclosure, and FIG. 2 is a schematic diagram of a leakage monitoring and prediction system 1 according to some embodiments of the disclosure. As shown in the figure, the leakage monitoring and prediction system 1 includes a receiving module 2, a processor 3, and a storage module 4. The processor 3 is electrically connected to the receiving module 2 and the storage module 4. The receiving module 2 is configured to receive a real-time audio signal N generated by the flow of fluid within a pipeline P, and the processor 3 is configured to convert the real-time audio signal N into a time-frequency spectrum and perform image recognition on the time-frequency spectrum, to determine whether leakage has occurred in the pipeline P.

In an embodiment, the leakage monitoring and prediction system 1 man be installed within an electronic device D. The electronic device D may be a network server, an artificial intelligence (AI) server, a data center, a switch, a high-performance computing (HPC) machine, or another electronic device that generates high heat. A plurality of pipelines P and a plurality of water-cooled plates D1 are arranged on the electronic device D. Each of the water-cooled plates D1 is arranged on a chip or an electronic component that generates high heat, and each of the pipelines P is in communication with the water-cooled plate D1 and a coolant monitoring host CDU. The coolant monitoring host CDU is mainly responsible for supplying a low-temperature coolant to the water-cooled plate D1. The coolant in the water-cooled plate D1 absorbs the heat generated by the chip or the electronic component, and then flows back to the coolant monitoring host CDU for heat exchange to reduce a temperature of the coolant. This process continuously circulates the coolant.

In some embodiments, the receiving module 2 is arranged on one side of the fluid cooling pipeline P of the electronic device D, and continuously receives the real-time audio signal N generated by the flow of the cooling fluid within the pipeline P. Furthermore, the receiving module 2 may include an automotive audio bus (A2B) 21 and a plurality of miniature microphone units 22. The miniature microphone units 22 may be microphones for micro-electromechanical systems (MEMSs), are arranged in a daisy chain configuration, and are electrically connected to the automotive audio bus 21. Based on the above, the miniature microphone units 22 are arranged in the daisy chain configuration. Therefore, each daisy chain unit includes four miniature microphone units 22, so as to improve accuracy of interpretation and facilitate marking of a leakage point. In addition, the adoption of the automotive audio bus 21 enhances scalability, allowing for continuous extension of miniature receiving units 22 as required by implementation needs. Moreover, the automotive audio bus 21 features fixed delay characteristics at each audio node, which reduces errors caused by inconsistent signal delays

In some embodiments, the processor 3 may be, for example, a central processing unit (CPU), a graphics processing unit (GPU), or another programmable microprocessor, a digital signal processor (DSP), a programmable controller, an application specific integrated circuit (ASIC), a programmable logic device (PLD), or another similar device.

In some embodiments, the storage module 4 may be, for example, any type of fixed or removable random access memory, read-only memory, flash memory, or hard disk, or another similar device, or a combination thereof. The storage module 4 includes a database 41 and a classification model 42. The database 41 stores a training dataset, which comprises pre-collected audio data from known cases (serving as actual condition results) of both leakage and non-leakage. These known audio data for leakage and non-leakage are used to build and train the classification model 42. Herein, the classification model 42 is, for example, a neural network (NN) model including a plurality of layers. The neural network model is trained through deep learning. The concept of deep learning involves providing the neural network model with a large volume of known data to establish the relationship between inputs and outputs. Through this process, parameters such as weights and biases in the neural network model are adjusted.

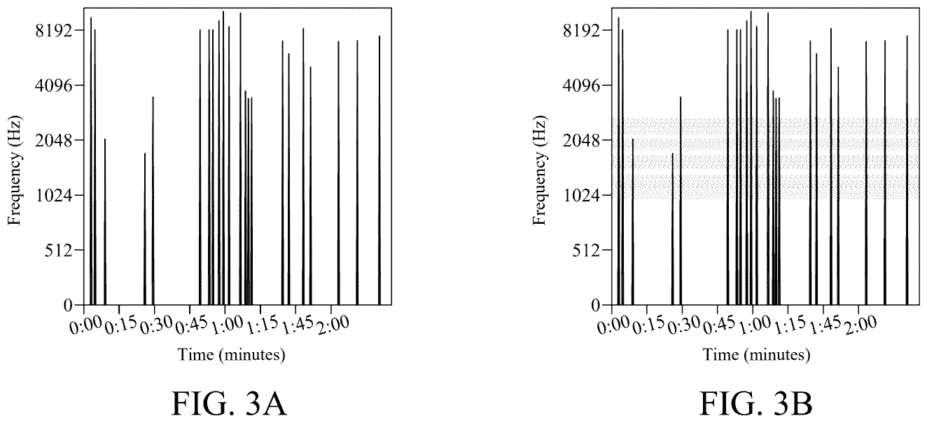

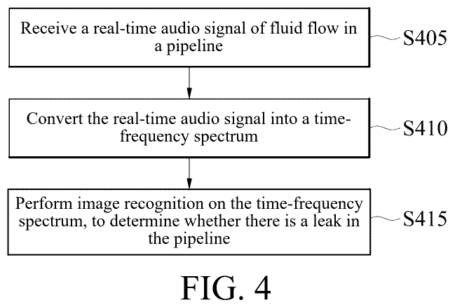

Referring to FIG. 3A, FIG. 3B, and FIG. 4 together, FIG. 3A is a schematic diagram of a time-frequency spectrum without leakage; FIG. 3B is a schematic diagram of a time-frequency spectrum during continuous leakage, and FIG. 4 is a flowchart illustrating the main steps of a leakage monitoring and prediction method according to some embodiments of the disclosure. According to some embodiments, a receiving module 2 receives a real-time audio signal N of fluid flow in a pipeline P, that is, step S405. A processor 3 converts the real-time audio signal N into a time-frequency spectrum, that is, step S410, and performs image recognition on the time-frequency spectrum to determine whether there is a leak in the pipeline P, step S415.

As shown in the time-frequency spectrograms in FIGS. 3A and 3B, the patterns correspond to scenarios without leakage and with leakage, respectively. In FIG. 3A, only isolated spikes are visible, representing ambient audio signals, such as noise generated by impacts or vibrations of components. In contrast, FIG. 3B shows not only isolated spikes but also continuous audio signals, which are distinctive audio signals produced by continuous leakage in the pipeline P. Generally, leaks in metal pipelines transmit sound at higher frequencies, with an audio range between 500 Hz and 1500 Hz. On the other hand, leaks in plastic or PVC pipelines exhibit lower frequency ranges, typically between 70 Hz and 850 Hz.

In step S410, the processor 3 performs fast Fourier transform on the real-time audio signal N, to generate the time-frequency spectrum. However, in some embodiments, the time-frequency spectrum may be a three-dimensional spectrum, and the three-dimensional spectrum includes time information, frequency information, sound intensity information. In some other embodiments, the time-frequency spectrum may be a two-dimensional spectrum. A purpose of converting the real-time audio signal N into the time-frequency spectrum through the fast Fourier transform is that after a time-domain signal is converted into the time-frequency spectrum, an audio signal generated in the presence of a leak shows a temporally-continuous phenomenon of energy clustering in the time-frequency spectrum, and any subtle feature of the sound can be retained without being lost during the transformation, which facilitates subsequent determining of whether there is a leak by using a computer vision technology.

In step S415, the processor 3 inputs the time-frequency spectrum obtained through the conversion into a classification model 42, to generate a leak determining result of the pipeline P. In some embodiments, the classification model 42 may be a support vector machine classification model SVM. The classification model 42 herein may be trained by the processor 3 itself, or may be a trained classifier obtained from another processing device. The present invention is not limited herein.

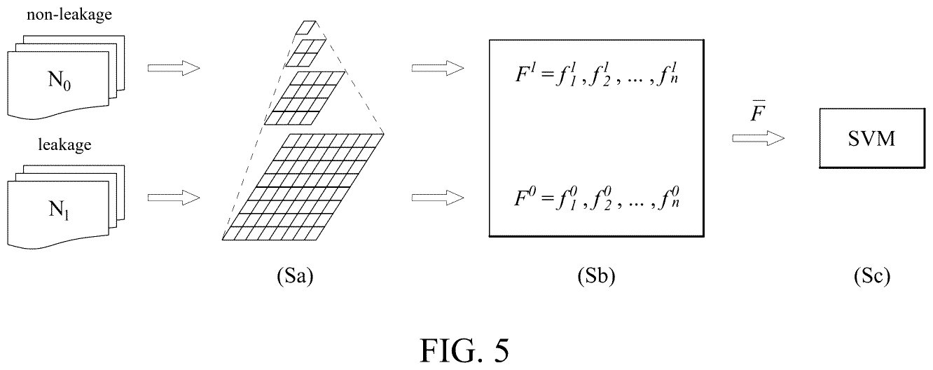

Referring to FIG. 5 together, FIG. 5 is a schematic diagram illustrating the establishment of a classification model 42 in a leakage monitoring and prediction method according to some embodiments of the disclosure. In some embodiments, establishing the classification model 42 includes the following steps: First, a plurality of time-frequency spectra corresponding to leakage and non-leakage conditions are provided. All of the time-frequency spectra are associated with known leakage or non-leakage outcomes and include patterns with both clear and unclear characteristics. Next, the processor 3 performs image pyramid processing on the time-frequency spectra in sequence, to generate images at different scales, that is, step Sa in FIG. 5. Furthermore, the processor 3 performs feature extraction processing on the image generated in the previous step, that is, step Sb in FIG. 5. Finally, the processor 3 outputs the image to a support vector machine classification model SVM for classification, that is, step Sc in FIG. 5, and establishes the classification model 42 based on the above.

More specifically, in some embodiments, the classification model 42 leveraging artificial intelligence (AI) analyzes the data by first recording all sound and establishing a training database. The training database includes a large volume of normal, non-leakage audio data, as well as a variety of abnormal audio data that has been filtered and labeled. These abnormal audio samples encompass various environmental transient noises and leakage modes confirmed through manual verification. Once the classification model 42 is sufficiently trained on these samples, it becomes capable of distinguishing leakage sounds from complex background noise.

Furthermore, in some embodiments, the sound data is analyzed and recorded as a three-dimensional spectrogram (including time, frequency, and volume). Since leakage may involve very faint but continuous audio patterns, which could be mixed with a lot of background equipment noise, it is necessary to manually select and categorize these patterns as abnormal training samples. These are then supplemented with a large number of normal samples and non-leakage abnormal samples. After machine learning, the classification model 42 is able to distinguish leakage sounds from other types of noise.

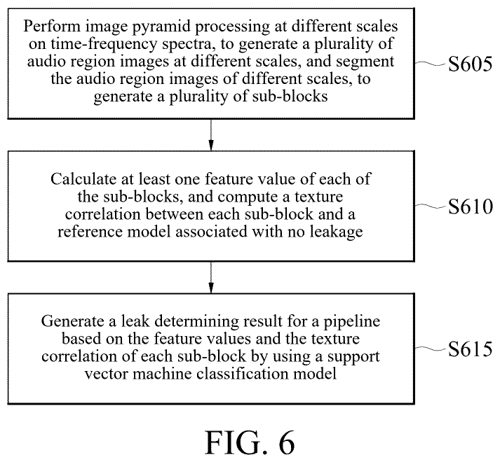

Referring to FIG. 6 together, FIG. 6 is a flowchart illustrating the leakage determination process in a leakage monitoring and prediction method according to some embodiments of the disclosure. In an embodiment, specific steps of inputting the time-frequency spectrum into the classification model 42, to generate the leak determining result for the pipeline P are described below. First, the processor 3 performs image pyramid processing at different scales on time-frequency spectra, to generate a plurality of audio region images with varying scales. Next, the processor 3 segments the audio region images of different scales, to generate a plurality of sub-blocks, where the plurality of sub-blocks have a same size, that is, step S605 in FIG. 6.

Next, in step S610, the processor 3 calculates at least one feature value of each of the sub-blocks, and computes a texture correlation between each sub-block and a reference model associated with no leakage. In some embodiments, the creation of the reference model includes the following steps: performing image pyramid processing on the plurality of time-frequency spectrograms with no leakage, then averaging the pixel values of the resulting sub-time-frequency spectra to obtain the reference model; where each of the sub-time-frequency spectra has the same size.

In some embodiments, the processor 3, for example, may calculate a standard deviation and histogram kurtosis of pixel values of each sub-block as the feature value of each sub-block. Certainly, in other embodiments, both of the standard deviation and the histogram kurtosis may be used together to calculate the feature value of each sub-block, thereby obtaining more accurate results. In addition, in some embodiments, the texture correlation between each sub-block and the reference model may be a correlation coefficient of a local binary pattern (LBP) between the sub-block and the reference model.

Finally, in step S615, the support vector machine classification model SVM is used to generate the leak determining result for the pipeline P based on the feature values and texture correlations of each sub-block. Specifically, the processor 3 inputs the feature values and texture correlations corresponding to each sub-block into the classification model 42 (the support vector machine classification model SVM), which produces an output indicating whether a leak has occurred.

In some embodiments, such as during the initial setup of the system or the fine-tuning process of the module, further verification of the system's leak determining result is required. The following method for verifying the leak determining result is provided, which includes the following steps: After obtaining the leak determining result, manually verify whether the result matches the actual status. If the leak determining result does not align with the actual status, the processor 3 inputs the time-frequency spectrum into a training dataset, so that the classification model 42 can be retrained using the training dataset. The actual status can be obtained through visual observation, manual inspection, or other leak detection systems. In some embodiments, the training dataset is stored in the database 41 of the storage module 4.

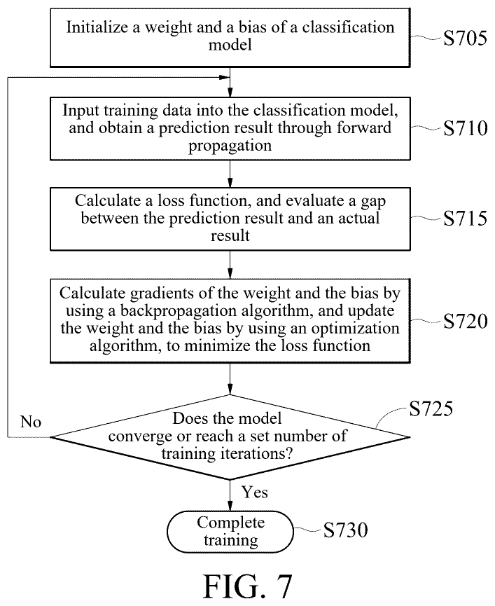

Referring to FIG. 7, FIG. 7 is a flowchart illustrating the training of a classification model 42 in a leakage monitoring and prediction method according to some embodiments of the disclosure. The following provides a method for refining and tuning the classification model 42, which is applicable when there is an error in the leak detection result. This method allows the classification model 42 to be retrained. First, in step S705, initialize a weight and a bias of the classification model 42. Next, in Step S710, input training data into the classification model 42, and obtain a prediction result through forward propagation. Furthermore, in step S715, calculate a loss function, and evaluate the gap between the prediction result and an actual result. Then, in step S720, calculate gradients of the weight and the bias by using a backpropagation algorithm, and update the weight and the bias by using an optimization algorithm, to minimize the loss function. This process is repeated from step S710 to step S720 until the model converges or reaches the set number of training iterations, as specified in step S725. The classification model 42 training process is then completed, as outlined in step S730.

In addition, in some embodiments, after completing the training of the classification model 42, the following steps can be performed for fine-tuning: First, use test data to predict with the classification model 42 and evaluate the model's performance. Next, based on the evaluation results, adjust the model architecture, hyperparameters, or retrain the model. These steps are aimed at continuously refining the classification model 42 to improve the accuracy and efficiency of the leak detection judgment.

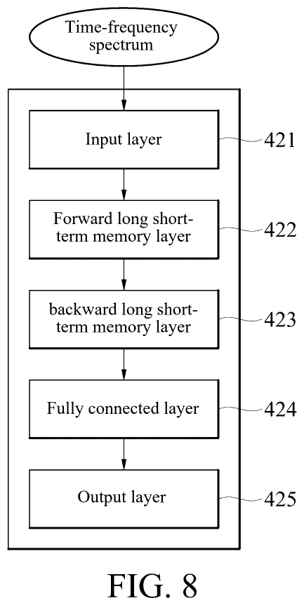

Referring to FIG. 8, it is an architecture diagram of a bidirectional long short-term memory (BLSTM) model used in a leakage monitoring and prediction method according to some embodiments of the disclosure. In other embodiments, the classification model 42 can also adopt a bidirectional long short-term memory (BLSTM) model, which, in addition to determining the occurrence of a leakage, can further analyze the pattern, scale, and location of the leakage in other embodiments.

In some embodiments, the bidirectional long short-term memory model includes an input layer 421, a forward long short-term memory layer 422, a backward long short-term memory layer 423, a fully connected layer 424, and an output layer 425. The input layer 421 is configured to input the time-frequency spectrum, the forward long short-term memory layer 422 is configured to process forward sequence data in the time-frequency spectrum, the backward long short-term memory layer 423 is configured to process backward sequence data in the time-frequency spectrum, the fully connected layer 424 is configured to integrate outputs of the forward long short-term memory layer 422 and the backward long short-term memory layer 423, and the output layer 425 is configured to output a corresponding leak determining result.

In a further description, the time-frequency spectrum inputted to the input layer 421 may be divided into a plurality of sub-time-frequency spectra based on a time sequence of the time-frequency spectrum (from low frequency to high frequency). Next, the forward long short-term memory layer 422 performs forward sequence data calculation on each of the sub-time-frequency spectra to obtain feature data. Moreover, the backward long short-term memory layer 423 performs backward sequence data calculation on each sub-time-frequency spectrum to obtain another set of feature data. Then, the fully connected layer 424 integrates the feature data respectively outputted by the forward long short-term memory layer 422 and the backward long short-term memory layer 423, and after calculating the weights, a probability is obtained. Finally, the output layer 425 outputs the corresponding leak determining result based on the probability. In other embodiments, the fully connected layer 424 further transmits information such as the leak location and the scale of the leak to the output layer 425. The output layer 425 not only outputs the leak determining result, but also simultaneously outputs the information such as the leak location and the scale of the leak.

In summary, due to the fact that highly sensitive sound recording systems capture all sounds from the system environment, including air conditioning, occasional events, heat dissipation fans, pumps, and cabinet resonance, the noise generated by server cooling liquid pipe leaks is typically very low in volume and difficult to detect. Therefore, in some embodiments, an AI classification model 42, which combines machine deep learning, is employed to distinguish leak noise from the mixed background noise.

Furthermore, in some embodiments, the leakage monitoring and prediction system 1 continuously collects sound signals in real time and inputs them into the classification model 42 for analysis. When an abnormal sound (for example, a coolant leak) is detected, the system immediately triggers an alarm and records a location, a scale, and time of the leak, allowing maintenance personnel to address the issue promptly. In addition, through an integrated data management module, the system can store and analyze historical sound data, and generate a report, to help a manager understand an operating status of an apparatus and perform preventive maintenance.

Additionally, in some embodiments, the training dataset may include a collection of known early-stage minor leaks or audio data from pipeline P or their joints before a leak occurs, used to establish and train the classification model 42. Furthermore, in some embodiments, since the miniature microphones units 22 are the microphones of the MEMSs have actual dimensions of approximately 2 mm to 3 mm, they are capable of detecting very small vibrations (acceleration) and sound wave motion. This makes them suitable for sensing the vibrations (acceleration) and sound wave motion of pipeline P or joints that are at the early stages of leaking or about to leak. Therefore, in addition to real-time monitoring and leak detection, this system can further enable the prediction and prevention of leaks. That is, when early signs of leakage occur, such as a change in the flow path or flow pattern of fluid inside the pipeline P or its joints, the system will immediately issue an alarm, enabling leak prediction and prevention.

Although the disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A method for monitoring and predicting a leak in a liquid cooling system of an electronic device, the method comprising:
receiving a real-time audio signal of fluid flow within a pipeline;
converting the real-time audio signal into a time-frequency spectrum; and
performing image recognition on the time-frequency spectrum, to determine whether there is a leak in the pipeline.

2. The method for monitoring and predicting a leak according to claim 1, wherein the step of converting the audio signal into the time-frequency spectrum comprises:
performing fast Fourier transform on the real-time audio signal, to generate the time-frequency spectrum, wherein the time-frequency spectrum is a three-dimensional spectrum, and the three-dimensional spectrum comprises time information, frequency information, and sound intensity information.

3. The method for monitoring and predicting a leak according to claim 1, wherein the step of determining whether there is the leak in the pipeline based on the time-frequency spectrum comprises:
inputting the time-frequency spectrum into a classification model, to generate a leak determining result of the pipeline.

4. The method for monitoring and predicting a leak according to claim 3, wherein the classification model is a neural network (NN) model.

5. The method for monitoring and predicting a leak according to claim 4, wherein the classification model comprises a bidirectional long short-term memory (BLSTM) model, comprising an input layer, a forward long short-term memory layer, a backward long short-term memory layer, a fully connected layer, and an output layer, wherein the input layer is configured to receive the time-frequency spectrum, the forward long short-term memory layer is configured to process forward sequence data in the time-frequency spectrum, the backward long short-term memory layer is configured to process backward sequence data in the time-frequency spectrum, the fully connected layer is configured to integrate outputs of the forward long short-term memory layer and the backward long short-term memory layer, and the output layer is configured to output the corresponding leak determining result.

6. The method for monitoring and predicting a leak according to claim 5, wherein after obtaining the leak determining result, the method further comprises: determining whether the leak determining result matches a result of an actual current condition; and inputting the time-frequency spectrum into a training dataset to retrain the classification model through the training dataset if the leak determining result does not match the result of the actual current condition.

7. The method for monitoring and predicting a leak according to claim 6, wherein the training dataset comprising the following steps:
initializing a weight and a bias of the classification model;
inputting training data into the classification model, and obtaining a prediction result through forward propagation;
calculating a loss function, and evaluating a difference between the prediction result and an actual result;
calculating gradients of the weight and the bias by using a backpropagation algorithm, and updating the weight and the bias by using an optimization algorithm, to minimize the loss function; and
repeating the above steps until the model converges or reaches a set number of training iterations.

8. The method for monitoring and predicting a leak according to claim 7, wherein after the training of the classification model is completed, the method comprises the following steps:
using test data to perform predictions with the classification model, and evaluating performance of the model; and
adjusting a model architecture and a hyperparameter or retraining the model based on an evaluation result.

9. The method for monitoring and predicting a leak according to claim 3, wherein the classification model comprises a support vector machine classification model.

10. The method for monitoring and predicting a leak according to claim 9, wherein establishing the classification model comprises the following steps:
providing a plurality of time-frequency spectra corresponding to leakage and non-leakage conditions, performing image pyramid processing and feature extraction processing on the time-frequency spectra in sequence, and then outputting the processed data to the support vector machine classification model for classification.

11. The method for monitoring and predicting a leak according to claim 9, wherein the inputting the time-frequency spectrum into a classification model, to generate a leak determining result of the pipeline comprises the following steps:
performing image pyramid processing at different scales on time-frequency spectra, to generate a plurality of audio region images with varying scales, and segmenting the audio region images of different scales to generate a plurality of sub-blocks;
calculating at least one feature value of each of the sub-blocks, and determining a texture correlation between each sub-block and a reference model associated with non-leakage conditions; and
generating the leak determining result of the pipeline based on the feature value and the texture correlation of each sub-block by using the support vector machine classification model.

12. The method for monitoring and predicting a leak according to claim 11, wherein establishing the reference model comprises the following steps:
averaging pixel values of sub-time-frequency spectra obtained from performing the image pyramid processing on the time-frequency spectra corresponding to non-leakage conditions, to generate the reference model.

13. The method for monitoring and predicting a leak according to claim 11, wherein the at least one feature value of each sub-block comprises at least one of a standard deviation and histogram kurtosis of a plurality of pixel values of the sub-block.

14. The method for monitoring and predicting a leak according to claim 11, wherein the texture correlation between each sub-block and the reference model is a correlation coefficient of a local binary pattern (LBP) between the sub-block and the reference model.

15. A system for monitoring and predicting a leak in a liquid cooling system of an electronic device, the system comprising:
a receiving module, configured to receive a real-time audio signal of fluid flow within a pipeline; and
a processor, coupled to the receiving module, and configured to convert the real-time audio signal into a time-frequency spectrum and perform image recognition on the time-frequency spectrum, to determine whether there is a leak in the pipeline.

16. The system for monitoring and predicting a leak according to claim 15, wherein the receiving module comprises an automotive audio bus (A2B) and a plurality of miniature microphone units, and the miniature microphone units are arranged in a daisy chain configuration and are electrically connected to the automotive audio bus.

17. The system for monitoring and predicting a leak according to claim 15, wherein the receiving module is arranged on a side of a fluid cooling pipeline of an electronic device, and is adapted to continuously receive the real-time audio signal generated by cooling fluid flow in the fluid cooling pipeline.

18. A system for monitoring and predicting a leak in a liquid cooling system of an electronic device, the system comprising:
a receiving module, configured to receive a real-time audio signal of fluid flow within a pipeline; and
a processor, coupled to the receiving module, and configured to perform fast Fourier transform on the real-time audio signal, to generate a time-frequency spectrum, and input the time-frequency spectrum into a classification model to perform image recognition, so as to determine whether there is a leak in the pipeline.

19. The system for monitoring and predicting a leak according to claim 18, wherein the classification model comprises a bidirectional long short-term memory (BLSTM) model, comprising an input layer, a forward long short-term memory layer, a backward long short-term memory layer, a fully connected layer, and an output layer, wherein the input layer is configured to receive the time-frequency spectrum, the forward long short-term memory layer is configured to process forward sequence data in the time-frequency spectrum, the backward long short-term memory layer is configured to process backward sequence data in the time-frequency spectrum, the fully connected layer is configured to integrate outputs of the forward long short-term memory layer and the backward long short-term memory layer, and the output layer is configured to output a corresponding leak determining result.

20. The system for monitoring and predicting a leak according to claim 18, wherein the classification model comprises a support vector machine classification model, and the processor is configured to: perform image pyramid processing at different scales on time-frequency spectra, to generate a plurality of audio region images with varying scales, and segment the audio region images of different scales, to generate a plurality of sub-blocks; calculate at least one feature value of each of the sub-blocks, and calculate a texture correlation between each sub-block and a reference model associated with non-leakage conditions; and generate a leak determining result of the pipeline based on the feature value and the texture correlation of each sub-block by using the support vector machine classification model.
